(19) United States
(12) Patent Application Publication
(10) Pub. No.: US 2011/0198213 A1
(43) Pub. Date: Aug. 18, 2011

(54) Sputtering Apparatus, Thin-Film Forming Method, and Manufacturing Method for a Field Effect Transistor

(75) Inventors: Takaomi Kurata, Chiba (JP); Junya Kiyota, Chiba (JP); Makoto Arai, Chiba (JP); Yasuhiko Akamatsu, Chiba (JP); Satoru Ishibashi, Chiba (JP); Kazuya Saito, Chiba (JP)

(73) Assignee: ULVAC, INC., Kanagawa (JP)

(21) Appl. No.: 13/123,720

(22) PCT Filed: Oct. 9, 2009
(86) PCT No.: PCT/JP2009/005282

§ 371 Date: Apr. 12, 2011

(30) Foreign Application Priority Data
Oct. 16, 2008 (JP) 2008-267469

(51) Int. Cl. C23C 14/34

(52) U.S. Cl. 204/192.25; 204/298.12; 204/192.12

(57) ABSTRACT

[Object] To provide a sputtering apparatus, a thin-film forming method, and a manufacturing method for a field effect transistor, which are capable of reducing damage of a base layer.

[Solving Means] The sputtering apparatus according to the present invention sputters target portions Tc1 to Tc5, which are arranged in an inside of a vacuum chamber, along the arrangement direction thereof in sequence, to thereby form a thin-film on a surface of a substrate 10. With this, rate at which sputtered particles enter the surface of the substrate in a direction oblique to the surface of the substrate is increased, and hence it is possible to achieve a reduction of the damage of the base layer.

### TECHNICAL FIELD

The present invention relates to a sputtering apparatus for forming a thin-film on a substrate, a thin-film forming method using the same, and a manufacturing method for a field effect transistor.

### BACKGROUND ART

Conventionally, in a step of forming a thin-film on a substrate, there has been used a sputtering apparatus. The sputtering apparatus includes a sputtering target (hereinafter, abbreviated as “target”) arranged in the inside of the vacuum chamber and a plasma generation means for generating plasma in vicinity of the surface of the target. The sputtering apparatus subjects the surface of the target to sputtering using ions in the plasma so that particles (sputtered particles) sputtered from the target are deposited on the substrate. In this manner, a thin-film is formed (for example, see Patent Document 1).

### CITED DOCUMENT

### Patent Document

Patent Document 1: Japanese Patent Application Laid-open No. 2007-39712

### DISCLOSURE OF THE INVENTION

### Problem to be solved by the Invention

A thin-film (hereinafter, also referred to as “sputtered thin-film”), which is formed by the sputtering method, has higher adhesion with respect to the substrate in comparison with a thin-film formed by a vacuum deposition method or the like because the sputtered particles incoming from the target are made incident on the surface of the substrate with high energy. Thus, a base layer (base film or base substrate) on which the sputtered thin-film is formed is easy to be greatly damaged due to collision of the incident sputtered particles. For example, when an active layer of a thin-film transistor is formed by the sputtering method, desired film properties may not be obtained due to the damage of the base layer.

In the above-mentioned circumstances, it is an object of the present invention to provide a sputtering apparatus, a thin-film forming method, and a manufacturing method for a field effect transistor, which are capable of reducing damage of a base layer.

### Means for Solving the Problem

A sputtering apparatus according to an embodiment of the present invention includes a vacuum chamber capable of keeping a vacuum state, a plurality of targets, a supporting portion, and a plasma generation means.

Each of the plurality of targets includes a surface to be sputtered, and the plurality of targets are linearly arranged in an inside of the vacuum chamber.

The supporting portion has a supporting region for supporting the substrate, and is fixed in the inside of the vacuum chamber.

The plasma generation means generates plasma for sputtering the surface to be sputtered of each of the targets, along an arrangement direction of the targets in sequence.

A thin-film forming method according to an embodiment of the present invention includes stabilizing a substrate in an inside of a vacuum chamber in which a plurality of targets are linearly arranged. Each of the targets is sputtered along the arrangement direction thereof in sequence, to thereby form a thin-film on a surface of the substrate.

A manufacturing method for a field effect transistor according to an embodiment of the present invention includes forming a gate insulating film on a substrate. The substrate is stabilized in an inside of a vacuum chamber in which a plurality of targets each having In—Ga—Zn—O-based composition are linearly arranged. Each of the targets is sputtered along the arrangement direction thereof in sequence, to thereby form an active layer on the gate insulating film.

### BRIEF DESCRIPTION OF DRAWINGS

FIG. 1 A schematic plan view showing a vacuum processing apparatus according to an embodiment of the present invention.

FIG. 2 A schematic view showing a mechanism for changing the posture of a substrate in a posture changing chamber.

FIG. 3 A plan view showing a schematic configuration of a sputtering apparatus constituting a first sputtering chamber in the vacuum processing apparatus.

FIG. 4 Schematic diagrams describing a typical operation example of the sputtering apparatus.

FIG. 5 A flow chart showing a processing order for the substrate in the vacuum processing apparatus.

FIG. 6 A schematic diagram of a main part, which describes another embodiment of the sputtering apparatus.

FIG. 7 A view showing a film thickness distribution of a thin-film formed by use of the sputtering apparatus of FIG. 6.

FIG. 8 A view describing an incident angle of sputtered particles incident on a substrate region corresponding to a point C of FIG. 7.

FIG. 9 Experimental results each showing a film-forming rate of the thin-film formed by use of the sputtering apparatus of FIG. 6.

FIG. 10 A view showing ON-state current characteristics and OFF-state current characteristics when each of samples of thin-film transistors manufactured by use of the sputtering apparatus of FIG. 6 is annealed at 200° C.

FIG. 11 A view showing ON-state current characteristics and OFF-state current characteristics when each of samples of thin-film transistors manufactured by use of the sputtering apparatus of FIG. 6 is annealed at 400° C.

FIG. 12 Schematic diagrams describing a modified example of the sputtering apparatus according to the embodiment of the present invention.

### DETAILED DESCRIPTION

A sputtering apparatus according to an embodiment of the present invention includes a vacuum chamber capable of keeping a vacuum state, a plurality of targets, a supporting portion, and a plasma generation means.

Each of the plurality of targets includes a surface to be sputtered, and the plurality of targets are linearly arranged in an inside of the vacuum chamber. The supporting portion has a supporting region for supporting the substrate, and is fixed in the inside of the vacuum chamber. The plasma generation means generates plasma for sputtering the surface to be sputtered of each of the targets, along an arrangement direction of the targets in sequence.

The above-mentioned sputtering apparatus forms the thin-film on the surface of the substrate on the supporting portion by sputtering the plurality of targets, which are arranged in the inside of the vacuum chamber, along the arrangement direction thereof in order. The sputtered particles are deposited on the surface of the substrate as if the sputtered particles pass along the substrate, and hence the film-forming form similar to that of a passing-type film-forming method can be obtained. With this, rate at which the sputtered particles enter the surface of the substrate in a direction oblique to the surface of the substrate is increased, and hence it is possible to achieve a reduction of damage of the base layer.

Here, “linearly arranged” means that the targets are arranged along the supporting portion, and it is not limited to precisely linear arrangement. Further, “the arrangement direction” means one direction along the arrangement direction of the targets.

A target portion of the plurality of targets, which is positioned on a most upstream side in the arrangement direction, may be positioned in an outside of the supporting region.

With this, the target portion is allowed to cause sputtered particles, which are generated when the target portion is sputtered, to enter the supporting portion in a direction oblique to the supporting portion.

The plasma generation means may include a magnet for forming a magnetic field on the surface to be sputtered. The magnet is arranged in each of the targets to be movable along the arrangement direction.

By setting the magnet to be movable, it is possible to easily control the incident angle of the sputtered particles with respect to the substrate.

The plurality of targets may be made of the same material.

With this, it is possible to form a thin-film of a predetermined material to have a desired film thickness while reducing the damage of the base layer.

A thin-film forming method according to an embodiment of the present invention includes stabilizing a substrate in an inside of a vacuum chamber in which a plurality of targets are linearly arranged. Each of the targets is sputtered along the arrangement direction thereof in sequence, to thereby form a thin-film on a surface of the substrate.

In the above-mentioned thin-film forming method, each of the plurality of targets arranged in the inside of the vacuum chamber is sputtered along the arrangement direction thereof in sequence, to thereby form the thin-film on the surface of the substrate. The sputtered particles are deposited on the surface of the substrate in such a manner that the sputtered particles cross the substrate, and hence the film-forming form similar to that of the passing-type film-forming method can be obtained. With this, rate at which the sputtered particles enter the surface of the substrate in a direction oblique to the surface of the substrate is increased, and hence it is possible to achieve a reduction of damage of the base layer.

A target portion of the plurality of targets, which is positioned on a most upstream side in the arrangement direction, may be positioned in an outside of a peripheral portion of the substrate.

With this, it is possible to cause sputtered particles, which are generated when the target portion is sputtered, to enter the substrate in a direction oblique to the substrate.

In each of the targets, a magnet for forming a magnetic field on the surface to be sputtered may be arranged. When each of the targets is being sputtered, the magnet arranged in the target being sputtered may be moved along the arrangement direction.

With this, it is possible to easily control the incident angle of the sputtered particles with respect to the substrate.

A manufacturing method for a field effect transistor according to an embodiment of the present invention includes forming a gate insulating film on a substrate. The substrate is stabilized in an inside of a vacuum chamber in which a plurality of targets each having In—Ga—Zn—O-based composition are linearly arranged. Each of the targets is sputtered along the arrangement direction thereof in sequence, to thereby form an active layer on the gate insulating film.

In the above-mentioned manufacturing method for a field effect transistor, each of the targets is sputtered along the arrangement direction thereof in sequence, to thereby form an active layer on the gate insulating film. The sputtered particles are deposited on the surface of the substrate in such a manner that the sputtered particles cross the substrate, and hence the film-forming form similar to that of the passing-type film-forming method can be obtained. With this, rate at which the sputtered particles enter the surface of the substrate in a direction oblique to the surface of the substrate is increased, and hence it is possible to achieve a reduction of damage of the base layer. Further, it is possible to stably manufacture the active layer of In—Ga—Zn—O-based composition, which has desired transistor properties.

Hereinafter, embodiments of the present invention will be described with reference to the drawings.

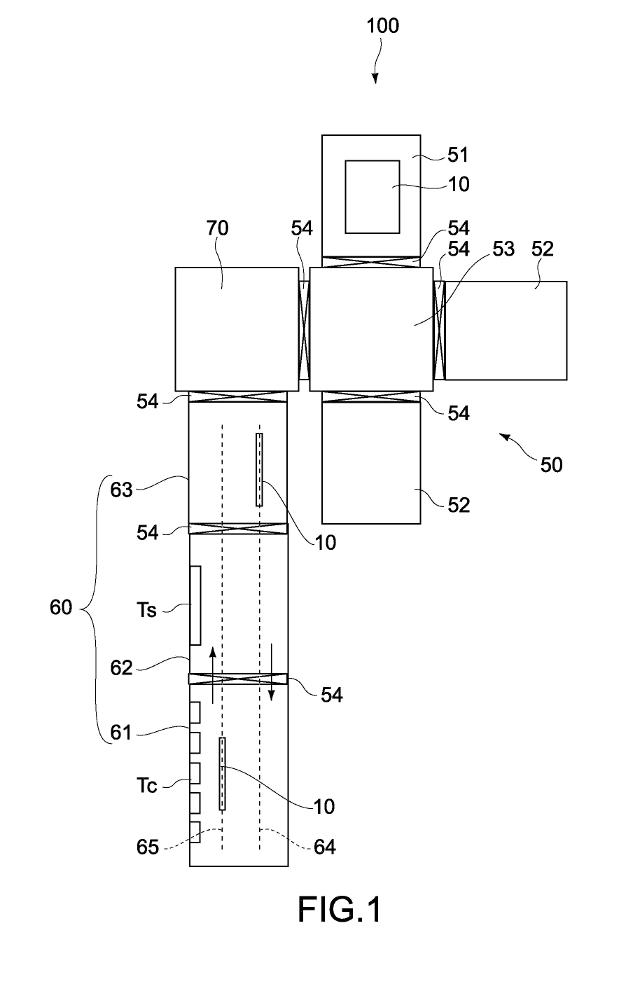

FIG. 1 is a schematic plan view showing a vacuum processing apparatus according to an embodiment of the present invention.

The vacuum processing apparatus 100 is an apparatus for processing a glass substrate (hereinafter, abbreviated as substrate) 10 to be used as a base material in a display, for example. Typically, the vacuum processing apparatus 100 is an apparatus responsible for a part of the manufacture of a field effect transistor having a so-called bottom gate type transistor structure.

The vacuum processing apparatus 100 includes a cluster type processing unit 50, an in-line type processing unit 60, and a posture changing chamber 70. Each of those chambers is formed in the inside of a single vacuum chamber or in the insides of combined vacuum chambers.

The cluster type processing unit 50 includes a plurality of horizontal type processing chambers. The plurality of horizontal type processing chambers process the substrate 10 in the state in which the substrate 10 is arranged substantially horizontally. Typically, the cluster type processing unit 50 includes a load lock chamber 51, a conveying chamber 53, and a plurality of CVD (Chemical Vapor Deposition) chambers 52.

The load lock chamber 51 switches between an atmospheric pressure state and a vacuum state, loads from the outside of the vacuum processing apparatus 100 the substrate 10, and unloads to the outside the substrate 10. The conveying chamber 53 includes a conveying robot (not shown). Each of the CVD chambers 52 is connected to the conveying chamber 53, and performs a CVD process with respect to the substrate 10. The conveying robot of the conveying chamber 53 carries the substrate 10 into the load lock chamber 51, each of the CVD chambers 52, and the posture changing chamber 70 to be described later. Further, the conveying robot of the conveying chamber 53 carries the substrate 10 out of each of the above-mentioned chambers.

In the CVD chambers 52, typically, a gate insulating film of the field effect transistor is formed.

It is possible to keep the conveying chamber 53 and the CVD chambers 52 under a predetermined degree of vacuum.

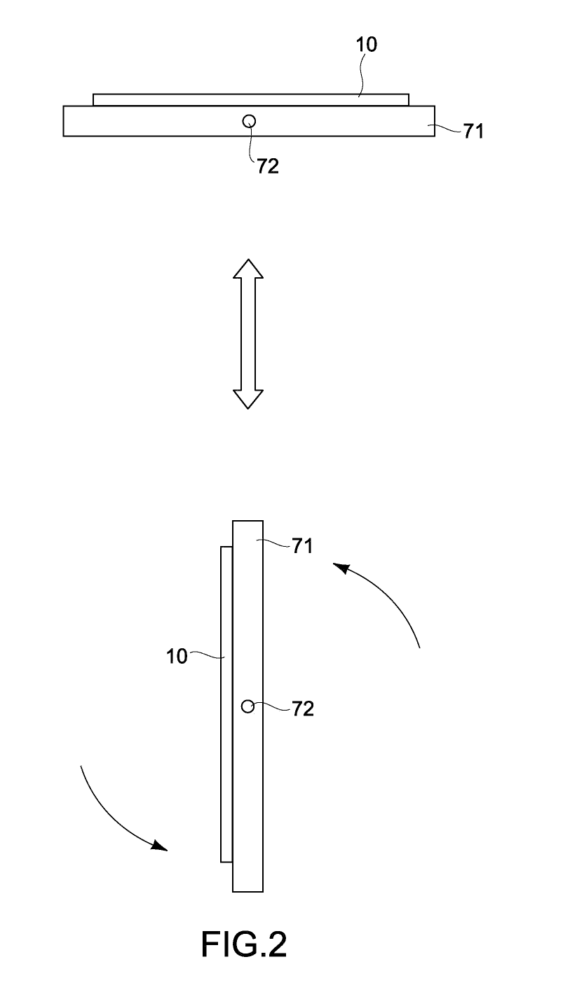

The posture changing chamber 70 changes the posture of the substrate 10 from the horizontal state to the vertical state and in turn, from the vertical state to the horizontal state. For example, as shown in FIG. 2, within the posture changing chamber 70, there is provided a holding mechanism 71 for holding the substrate 10. The holding mechanism 71 is configured to be rotatable about a rotating shaft 72. The holding mechanism 71 holds the substrate 10 by use of a mechanical chuck, a vacuum chuck, or the like. The posture changing chamber 70 can be kept under substantially the same degree of vacuum as the conveying chamber 53.

By driving a driving mechanism (not shown) connected to the both ends of the holding mechanism 71, the holding mechanism 71 may be rotated.

The cluster type processing unit 50 may be provided with a heating chamber and other chambers for performing other processes in addition to the CVD chambers 52 and the posture changing chamber 70, which are connected to the conveying chamber 53.

The in-line type processing unit 60 includes a first sputtering chamber 61, a second sputtering chamber 62, and a buffer chamber 63, and processes the substrate 10 in the state in which the substrate 10 is oriented substantially upright.

In the first sputtering chamber 61, typically, as will be described later, a thin-film having In—Ga—Zn—O-based composition (hereinafter, abbreviated as IGZO film) is formed on the substrate 10. In the second sputtering chamber 62, a stopper layer film is formed on that IGZO film. The IGZO film constitutes an active layer for the field effect transistor. The stopper layer film functions as an etching protection layer for protecting a channel region of the IGZO film from etchant in a step of patterning a metal film constituting a source electrode and a drain electrode and in a step of etching and removing an unnecessary region of the IGZO film.

The first sputtering chamber 61 includes a plurality of sputtering cathodes Tc each including a target material for forming the IGZO film. The second sputtering chamber 62 includes a single sputtering cathode Ts including a target material for forming the stopper layer film.

The first sputtering chamber 61 is, as will be described later, configured as a sputtering apparatus using a fixed-type film-forming method. On the other hand, the second sputtering chamber 62 may be configured as a sputtering apparatus using the fixed-type film-forming method or as a sputtering apparatus using a passing-type film-forming method.

Within the first and second sputtering chambers 61 and 62 and the buffer chamber 63, there are prepared two conveying paths for the substrate 10, which are constituted of a forward path 64 and a return path 65, for example. Further, a supporting mechanism (not shown) is provided for supporting the substrate 10 in the state in which the substrate 10 is oriented upright or in the state in which the substrate 10 is slightly inclined from the upright state. In this embodiment, a sputtering process is performed when the substrate 10 takes the return path 65. The substrate 10 supported by the supporting mechanism is adapted to be conveyed through conveying rollers and a mechanism such as a rack-and-pinion mechanism, which are not shown.

Between the chambers, gate valves 54 are respectively provided. The gate valves 54 are controlled independently of each other to be opened and closed.

The buffer chamber 63 is connected between the posture changing chamber 70 and the second sputtering chamber 62. The buffer chamber 63 functions as a buffering region for pressurized atmosphere of the posture changing chamber 70 and pressurized atmosphere of the second sputtering chamber 62. For example, when the gate valve 54 between the posture changing chamber 70 and the buffer chamber 63 is opened, the degree of vacuum of the buffer chamber 63 is controlled to be substantially equal to the pressure within the posture changing chamber 70. Alternatively, when the gate valve 54 between the buffer chamber 63 and the second sputtering chamber 62 is opened, the degree of vacuum of the buffer chamber 61 is controlled to be substantially equal to the pressure within the second sputtering chamber 62.

In the CVD chambers 52, in some cases, specialty gas such as cleaning gas is used for cleaning those chambers. For example, in a case where the CVD chambers 52 are configured as vertical type apparatuses, there is a fear that the supporting mechanism, the conveying mechanism, and the like, as provided in the above-mentioned sputtering chamber 62, which are peculiar to the vertical type processing apparatus, may be corroded due to the specialty gas, or the like. However, in the embodiment, the CVD chambers 52 are configured as the horizontal apparatuses, and hence the above-mentioned problem can be solved.

For example, in a case where the sputtering apparatus is configured as a horizontal apparatus, for example, when the target is arranged directly above the substrate, there is a fear that the target material adhering to the periphery of the target may drop on the substrate with a result that the substrate 10 may be contaminated. On the contrary, when the target is arranged under the base material, there is a fear that the target material adhering to a deposition preventing plate arranged in the periphery of the substrate may drop on an electrode with a result that the electrode may be contaminated. There is a fear that, due to the above-mentioned contaminations, an abnormal electrical discharge may occur during the sputtering process. However, the sputtering chamber 62 is configured as a vertical type processing chamber, and hence the above-mentioned problem can be solved.

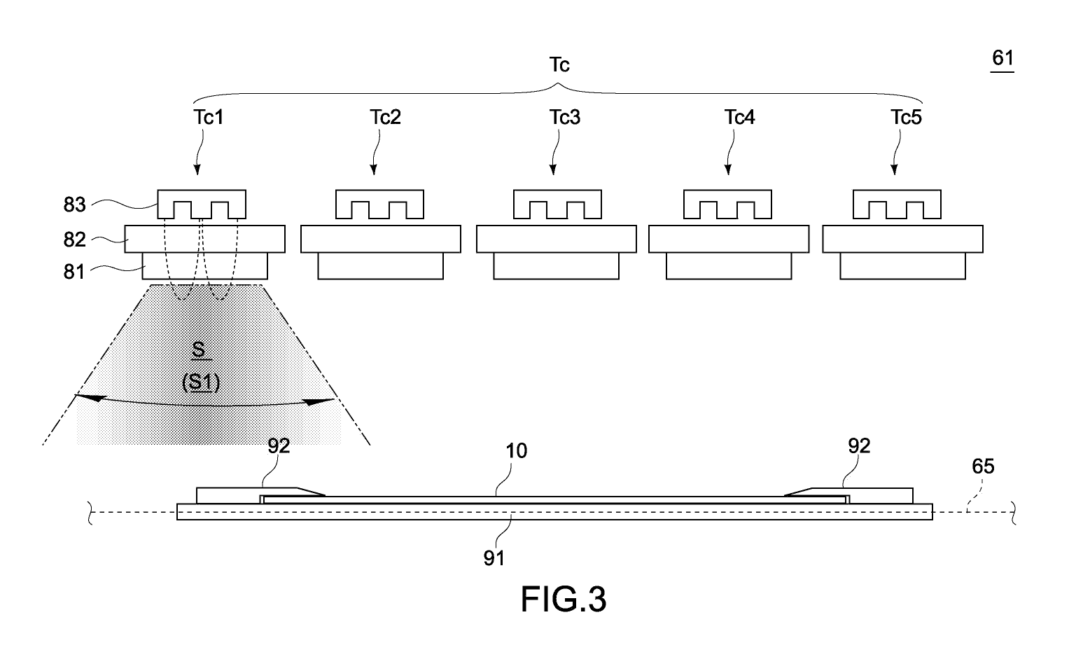

Next, the first sputtering chamber 61 will be described in detail. FIG. 3 is a schematic plan view showing a configuration of the sputtering apparatus constituting the first sputtering chamber 61.

The first sputtering chamber 61 includes the sputtering cathodes Tc including a plurality of target portions as described above. Each of the target portions Tc1, Tc2, Tc3, Tc4, and Tc5 has the same configuration, and includes a target plate 81, a backing plate 82, and a magnet 83. The first sputtering chamber 61 is connected to a gas introduction line (not shown). Through the gas introduction line, to the sputtering chamber 61, gas for sputtering such as argon and reactive gas such as oxygen are introduced.

The target plate 81 is constituted of an ingot of film-forming material or a sintered body. In this embodiment, the target plate 81 is constituted of an alloy ingot or a sintered body material having In—Ga—Zn—O composition. The backing plate 82 is configured as an electrode to be connected to an alternating-current power source (including high-frequency power source) or a direct-current power source, which are not shown. The backing plate 82 may include a cooling mechanism in which cooling medium such as cooling water is circulated. The magnet 83 is, typically, constituted of a combined body of a permanent magnet and a yoke. The magnet 8 forms a predetermined magnetic field 84 in the vicinity of a surface of the target plate 81 (surface to be sputtered).

The sputtering cathodes Tc configured in the above-mentioned manner generate plasma within the sputtering chamber 61 by use of a plasma generation means including the power sources, the magnet 83, the gas introduction line, and the like. That is, when predetermined alternating-current power or predetermined direct-current power is applied on the backing plate 81, plasma of gas for sputtering is generated in the vicinity of the surface to be sputtered of the target plate 81. Then, by ions in the plasma, the target plate 81 is sputtered. Further, a high density plasma (magnetron discharge) is generated due to the magnetic field formed on the target surface by the magnet 83, and hence it is possible to obtain density distribution of plasma, which corresponds to magnetic field distribution.

As shown in FIG. 3, sputtered particles generated when the target plate 81 is sputtered are emitted from the surface of the target plate 81 within an angle range S. The angle range S is controlled depending on formation conditions of plasma or the like. The sputtered particles include particles sputtered from the surface of the target plate 81 in a direction perpendicular to the surface of the target plate 81, and particles sputtered from the surface of the target plate 81 in a direction oblique to the surface of the target plate 81. The sputtered particles sputtered from the target plate 81 of each of the target portions Tc1 to Tc5 are deposited on the surface of the substrate 10 so that the thin-film is formed.

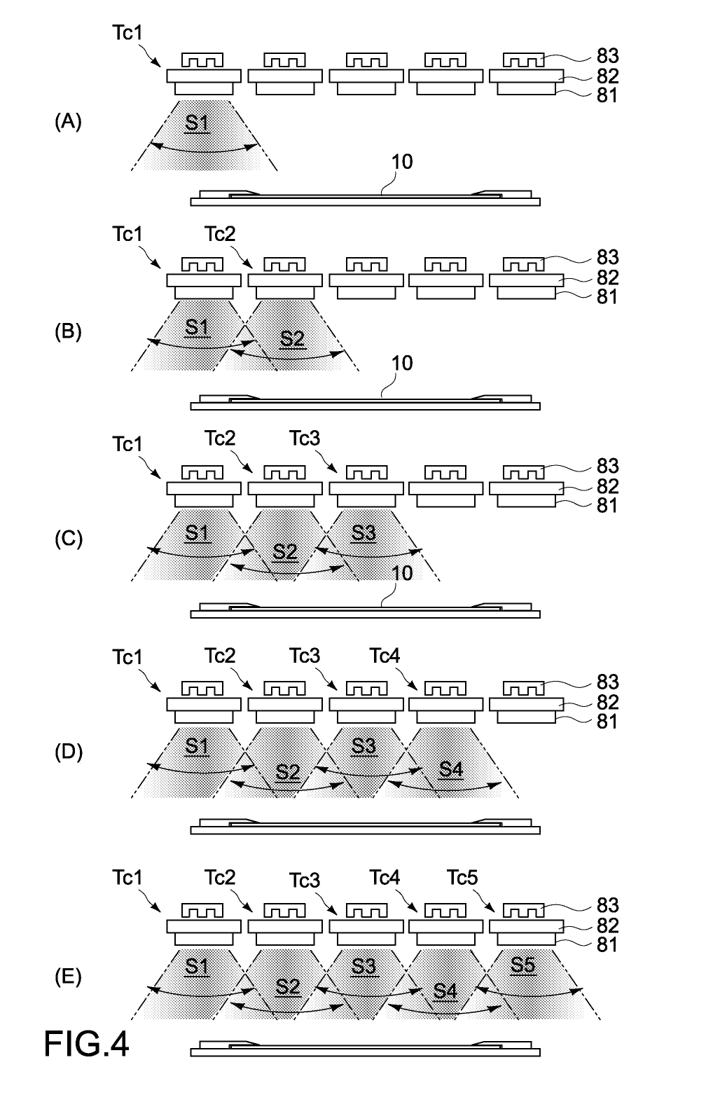

In this embodiment, as shown in FIG. 4, plasma for sputtering each of the target plates 81 is generated in the order of the target portions Tc1, Tc2, Tc3, Tc4, and Tc5. Then, the film-forming region of the substrate 10, which is defined by an emission angle (S1 to S5) of the sputtered particles sputtered from each target plate 81, is subjected to film formation in sequence. In order to realize the above-mentioned film-forming method, the sputtering apparatus includes a controller (not shown) for controlling a power supply to each of the target portions Tc1 to Tc5.

The target portions Tc1 to Tc5 are linearly arranged to cross the surface of the substrate 10 in the sputtering chamber 61. The substrate 10 is supported by a supporting mechanism (supporting portion) provided with a supporting plate 91 and clamp mechanisms 92. The substrate 10 is stabilized (fixed) at a predetermined position on the return path 65 during the film formation. The clamp mechanisms 92 hold the peripheral portion of the substrate 10 supported by the supporting region of the supporting plate 91 opposed to the sputtering cathodes Tc. A distance between each of the sputtering cathodes Tc and the supporting plate 91 which are opposed to each other is set to be the same.

The arrangement length of the target portions Tc1 to Tc5 is larger than the diameter of the substrate 10. In this case, the target portions Tc1 and Tc5 respectively positioned on the most upstream side and on the most downstream side are arranged to be opposed to the outside of the supporting region of the supporting plate 91. That is, for example, the target portion Tc1 is arranged at a position at which the sputtered particles Sp1, which are generated when the target portion Tc1 sputters its target plate 81, are incident on the surface of the substrate 10 in a direction oblique to the surface of the substrate 10.

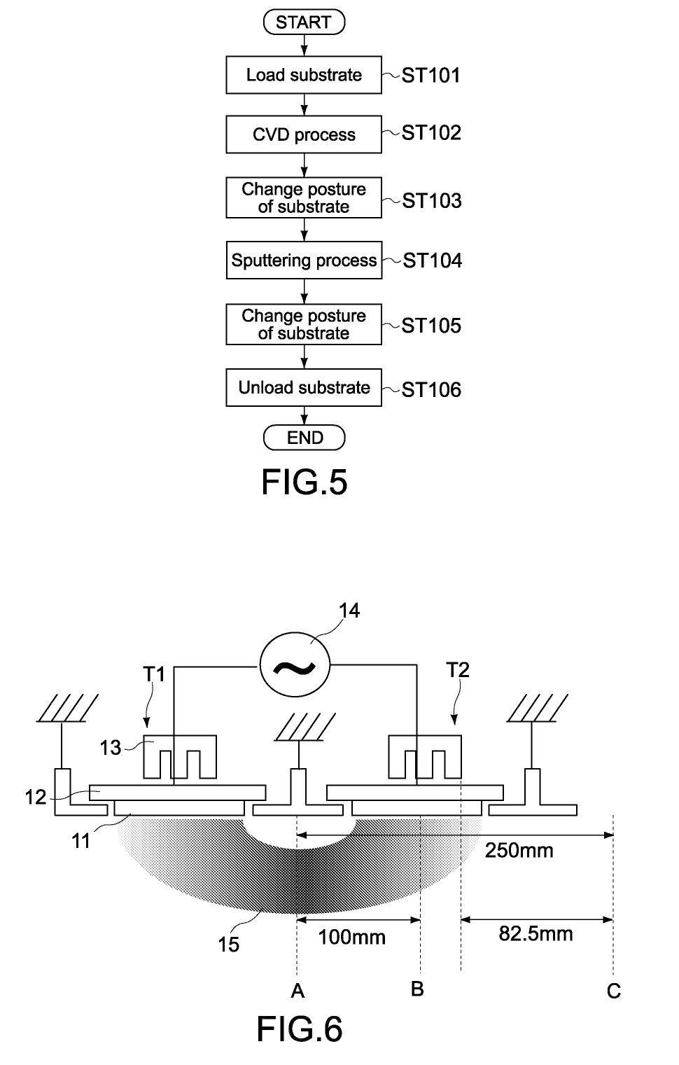

A processing order for the substrate 10 in the vacuum processing apparatus 100 configured in the above-mentioned manner will be described. FIG. 5 is a flow chart showing that order.

The conveying chamber 53, the CVD chambers 52, the posture changing chamber 70, the buffer chamber 63, the first sputtering chamber 61, and the second sputtering chamber 62 are each kept in a predetermined vacuum state. First, the substrate 10 is loaded in the load lock chamber 51 (Step 101). After that, the substrate 10 is conveyed through the conveying chamber 53 into the CVD chambers 52, and a predetermined film, for example, a gate insulating film is formed on the substrate 10 by the CVD process (Step 102). After the CVD process, the substrate 10 is conveyed through the conveying chamber 53 into the posture changing chamber 70, and the posture of the substrate 10 is changed from the horizontal posture to the vertical posture (Step 103).

The substrate 10 in the vertical posture is conveyed through the buffer chamber 63 into the sputtering chamber, and is further conveyed through the forward path 64 up to the end of the first sputtering chamber 61. After that, the substrate 10 takes the return path 65, is stopped within the first sputtering chamber 61, and is subjected to the sputtering process in the following manner. Thus, for example, an IGZO film is formed on the surface of the substrate 10 (Step 104).

With reference to FIG. 3, the substrate 10 is conveyed by the supporting mechanism within the first sputtering chamber 61, and is stopped at a position at which the first target portion Tc1 is opposed to an outside of the peripheral portion of the substrate 10. In the first sputtering chamber 61, argon gas and oxygen gas are introduced at a predetermined flow rate. Then, as shown in FIGS. 4(A) to 4(E), in such a manner that in the order of the target portions Tc1, Tc2, Tc3, Tc4, and Tc5, each plasma is generated, each target is sputtered. With this, the film-forming region of the substrate 10, which falls within the emission angle ranges S1 to S5 of the sputtered particles sputtered from each of the target portions Tc1 to Tc5, a film is subjected to film formation in sequence.

During this initial phase of the film formation, most of the sputtered particles arriving at the surface of the substrate 10 are the sputtered particles obliquely emitted from the target. Typically, the number of sputtered particles obliquely emitted from the target is smaller than the number of sputtered particles perpendicularly emitted from the surface of the target. Thus, the sputtered particles obliquely emitted from the surface of the target have lower energy density of the radiating sputtered particles per unit area in comparison with the sputtered particles perpendicularly emitted from the surface of the target. Correspondingly, it is possible to reduce the damage added to the surface of the substrate.

Therefore, according to the thin-film forming method of this embodiment, an initial layer of the thin-film is formed with the sputtered particles incident on the surface of the substrate 10 in a direction oblique to the surface of the substrate 10, and hence it is possible to form the sputtered thin-film without damaging the surface of the substrate. In particular, according to this embodiment, it is possible to form the IGZO film with small damage with respect to the gate insulating film on the substrate 10.

In order to form the initial layer of the thin-film over the entire region of the surface of the substrate 10 with the sputtered particles obliquely emitted from the target, each target portion is set so that two targets adjacent to each other satisfy the following conditions. That is, in such a manner that the sputtered particles obliquely emitted from one target can cover the film-forming region at which the sputtered particles perpendicularly emitted from the other target arrive, a distance between the targets and a distance between the target and the substrate are set. When the description is made by use of the example shown in FIG. 4, for example, the film-forming region of the substrate 10 in which the sputtered particles obliquely emitted from the target portion Tc1 positioned at the upstream side are deposited covers the film-forming region of the substrate 10 in which the sputtered particles perpendicularly emitted from the target portion Tc2 positioned at the downstream side are deposited. With this, it is possible to form the thin-film with small damage with respect to the base film over the entire region of the surface of the substrate 10.

Further, in the thin-film forming method of this embodiment, on the initial layer of the thin-film formed of the obliquely deposited film, the sputtered particles perpendicularly emitted from the target portion positioned at the downstream side are deposited. With this, the film-forming rate of the thin-film is suppressed from being lowered, and hence it is possible to prevent a reduction of the productivity.

The substrate 10 on which the IGZO film is formed within the first sputtering chamber 61 is conveyed to the second sputtering chamber 62 together with the supporting plate 91. In the second sputtering chamber 62, a stopper layer made of a silicon oxide film, for example, is formed on the surface of the substrate 10 (Step 104).

For the film-forming process in the second sputtering chamber 62, similarly to the film-forming process in the first sputtering chamber 61, the fixed-type film-forming method of forming a film with the substrate 10 being stabilized within the second film-forming chamber 62 is employed. The present invention is not limited thereto, the passing-type film-forming method of forming a film with the substrate 10 being passed through the second film-forming chamber 62 may be employed.

After the sputtering process, the substrate 10 is conveyed through the buffer chamber 61 into the posture changing chamber 70, and the posture of the substrate 10 is changed from the vertical posture to the horizontal posture (Step 105). After that, the substrate 10 is unloaded through the conveying chamber 53 and the load lock chamber 51 to the outside of the vacuum processing apparatus 100 (Step 106).

As described above, according to this embodiment, in the inside of one vacuum processing apparatus 100, it is possible to consistently perform CVD deposition and sputtering deposition without exposing the substrate 10 to the atmosphere. Thus, it is possible to achieve an increase of the productivity. Further, it is possible to prevent moisture and dust existing within the atmosphere from adhering to the substrate 10. Therefore, it is also possible to achieve an increase of the film quality.

In addition, according to this embodiment, the formation of the IGZO film in the first sputtering chamber 61 is performed by sputtering the plurality of linearly arranged target portions Tc1 to Tc5 along the arrangement direction in order. The sputtered particles are deposited on the surface of the substrate 10 in such a manner that the sputtered particles cross the substrate 10, and hence the film-forming form similar to that of the passing-type film-forming method can be obtained. With this, rate at which the sputtered particles enter the surface of the substrate 10 in a direction oblique to the surface of the substrate 10 is increased, and hence it is possible to achieve a reduction of the damage of the base layer. In particular, according to this embodiment, it is possible to reduce the damage of the gate insulating film being the base layer of the IGZO film, and hence it is possible to manufacture a field-effect thin-film transistor having high properties.

FIG. 6 is a view of a schematic configuration of the sputtering apparatus, which describes an experiment that the inventors of the present invention were performed. This sputtering apparatus included two target portions T1 and T2, each of which included a target plate 11, a backing plate 12, and a magnet 13. The backing plate 12 of each of the target portions T1 and T2 was connected to each electrode of an alternating-current power source 14. For the target plate 11, a target material of In—Ga—Zn—O composition was used.

A substrate having a surface on which a silicon oxide film was formed as the gate insulating film was arranged to be opposed to the target portions T1 and T2. The distance (TS distance) between the target portion and the substrate was set to 260 mm. The center of the substrate was set to correspond to a middle point (point A) between the target portions T1 and T2. The distance from this point A to the center (point B) of each of the target plate 11 was 100 mm. Oxygen gas at a predetermined flow rate was introduced into a vacuum chamber kept in depressurized argon atmosphere (flow rate 230 sccm, partial pressure 0.74 Pa), and each of the target plates 11 was sputtered with plasma 15 generated by applying alternating-current power (0.6 kW) between the target portions T1 and T2.

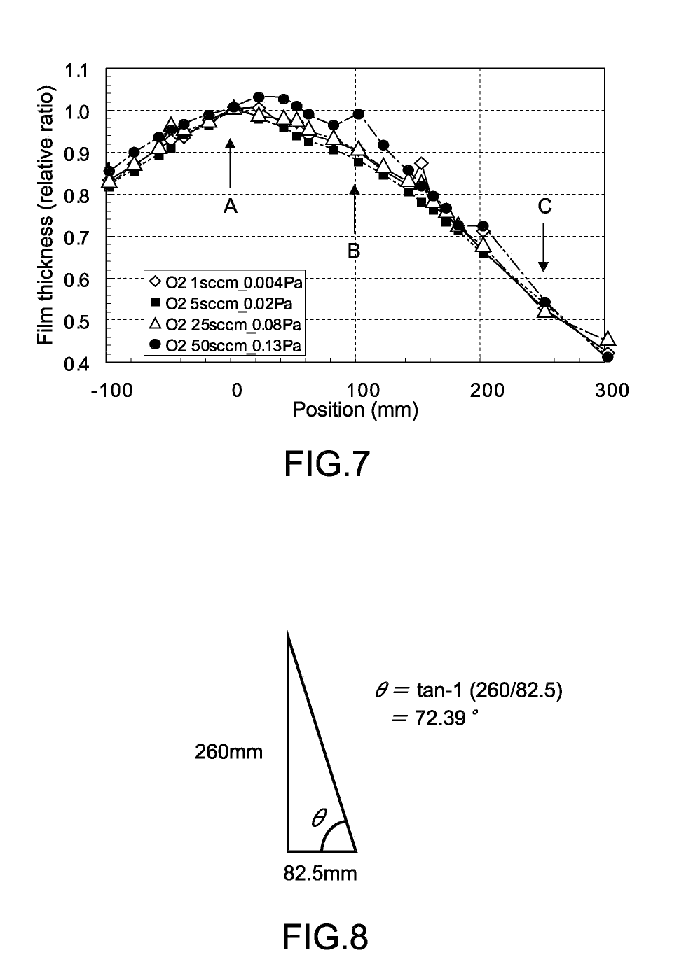

FIG. 7 shows measurement results of a film thickness at each position on the substrate, setting the point A as an original point. The film thickness at each point is represented as a relative ratio with respect to the film thickness of the point A set to 1. The temperature of the substrate was set to be equal to a room temperature. A point C indicates a position away from the point A by 250 mm. The distance from the outer periphery of the magnet 13 of the target portion T2 to the point C was 82.5 mm. In the drawing, a white diamond mark indicates a film thickness when the oxygen introduction amount was 1 sccm (partial pressure 0.004 Pa), a black square mark indicates a film thickness when the oxygen introduction amount was 5 sccm (partial pressure 0.02 Pa), a white triangle mark indicates a film thickness when the oxygen introduction amount was 25 sccm (partial pressure 0.08 Pa), and a black circle mark indicates a film thickness when the oxygen introduction amount was 50 sccm (partial pressure 0.14 Pa).

As shown in FIG. 7, the film thickness at the point A at which the sputtered particles emitted from the two target portions T1 and T2 arrived was the largest. The film thickness was reduced while going away from the point A. The point C was a deposition region of the sputtered particles obliquely emitted from the target portion T2, and hence the film thickness at the point C was smaller than that at the deposition region (point B) of the sputtered particles perpendicularly input from the target portion T2. An incident angle θ of the sputtered particles at this point C was 72.39° as shown in FIG. 8.

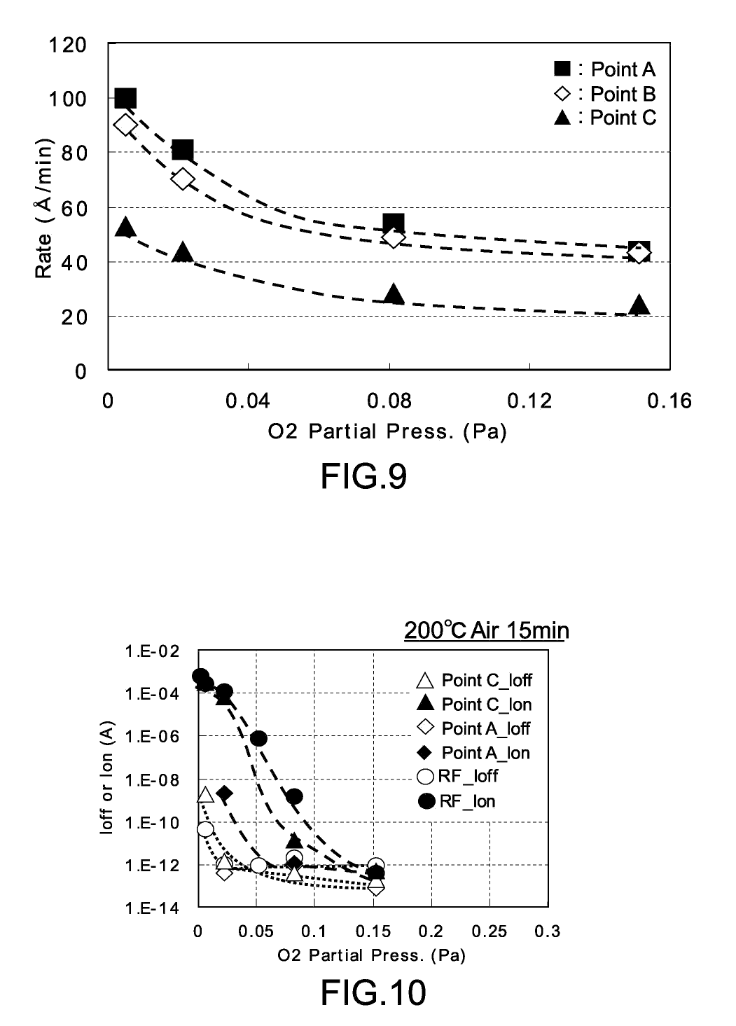

FIG. 9 is a view showing a relation between an introduced partial pressure and a film-forming rate, which was measured at each of the point A, the point B, and the point C. It was confirmed that irrespective of the film-forming position, as the oxygen partial pressure (oxygen introduction amount) becomes higher, the film-forming rate becomes lower.

At the point A and point C, thin-film transistors including the IGZO films, which were formed while varying the oxygen partial pressure, as the active layers were manufactured. By heating the sample of each transistor at 200° C. for 15 minutes in the atmosphere, the active layer was annealed. Then, with respect to each sample, ON-state current characteristics and OFF-state current characteristics were measured. The results are shown in FIG. 10. In the drawing, the vertical axis indicates ON-state current or OFF-state current, and the horizontal axis indicates an oxygen partial pressure during the formation of the IGZO film. As a reference, transistor properties of a sample including the IGZO film formed by an RF sputtering method using the passing-type film-forming method are shown together. In the drawing, a white triangle mark indicates an OFF-state current at the point C, a black triangle mark indicates an ON-state current at the point C, a white diamond mark indicates an OFF-state current at the point A, a black diamond mark indicates an ON-state current at the point A, a white circle mark indicates an OFF-state current of the reference sample, and a black circle mark indicates an ON-state current of the reference sample.

As will be clear from the results of FIG. 10, as the oxygen partial pressure becomes higher, the ON-state current decreases with respect to all of the samples. This is attributed to the fact that when oxygen concentration in the film becomes higher, the conductivity of the active layer becomes lower. Further, comparing the samples at the point A and the point C to each other, the sample at the point A has the ON-state current lower than that at the point C. This is attributed to the fact that during the formation of the active layer (IGZO film), a base film (gate insulating film) was greatly damaged due to collision of the sputtered particles, and hence the base film could not keep desired film quality. Further, the sample at the point C could obtain the ON-state current characteristics nearly equal to the ON-state current characteristics of the reference sample.

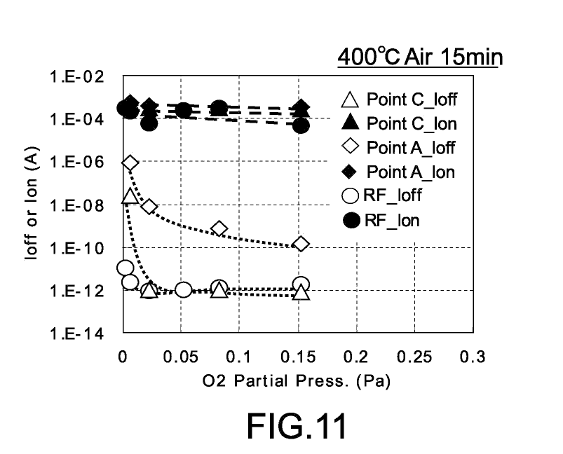

On the other hand, FIG. 11 shows results of an experiment in which the ON-state current characteristics and the OFF-state current characteristics of the thin-film transistor when the annealing condition of the active layer was set to be in the atmosphere, at 400° C., for 15 minutes were measured. Under this annealing condition, significant differences between the ON-state current characteristics of respective samples were not observed. However, it was confirmed that in regard to the OFF-state current characteristics, the sample at the point A is higher than each of the sample at the point C and the reference sample. This is attributed to the fact that during the formation of the active layer, the base film was greatly damaged due to collision of the sputtered particles, and hence the base film lost a desired insulating property.

Further, it was confirmed that by setting the annealing temperature to be high, it is possible to obtain high ON-state current characteristics without being affected by the oxygen partial pressure.

As will be clear from the above-mentioned results, in such a manner that when the active layer of the thin-film transistor is formed by sputtering, an initial layer of the thin-film is formed of the sputtered particles incident on the substrate in a direction oblique to the substrate, it is possible to obtain excellent transistor properties, that is, high ON-state current and low OFF-state current. Further, it is possible to stably manufacture the active layer of In—Ga—Zn—O-based composition, which has desired transistor properties.

Although the embodiments of the present invention have been described, it is needless to say that the present invention is not limited thereto and various modifications can be made based on the technical conception of the present invention.

For example, in the above-mentioned embodiments, in the sputtering apparatus constituting the first sputtering chamber 61, the magnet 83 of each of the target portions Tc1 to Tc5 is set to be fixed with respect to the target 81 (backing plate 82). Alternatively, the respective magnets 83 may be arranged so as to be movable along the arrangement direction of the target portions Tc1 to Tc5.

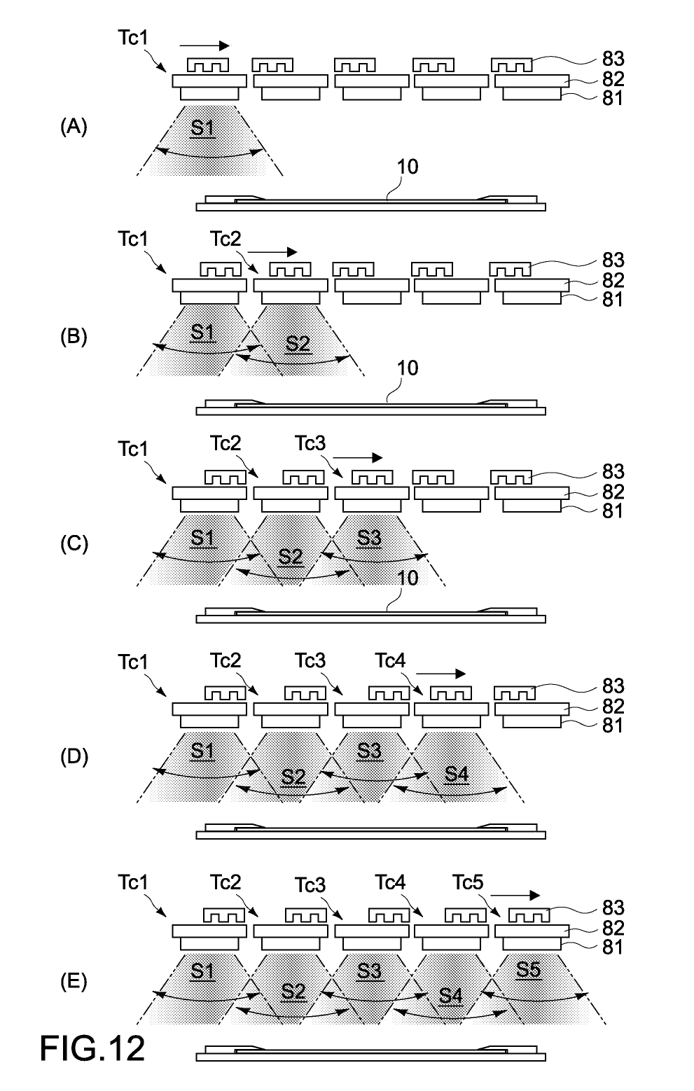

In this case, as shown in FIGS. 12(A) to 12(E), along the arrangement direction of the target portions, from the target portion Tc1 on the most upstream side to the target portion Tc5 on the most downstream side as seen from the substrate 10, the magnet 83 of each of the target portions being sputtered is moved. With this, it is possible to easily control the incident angle and the film-forming region of the sputtered particles incident on the substrate 10 in a direction oblique to the substrate 10. The moving speed of the magnet 83 can be appropriately set depending on the size of the target plate 81 and the magnet 83, and plasma-generating range, and the like.

Further, although in each of the above-mentioned embodiments, the description has been made by exemplifying the manufacturing method for the thin-film transistor including the IGZO film as the active layer, the present invention is also applicable in a case where a film made of another film-forming material such as a metal material is formed by sputtering.

### DESCRIPTION OF SYMBOLS

10 . . . substrate
50 . . . cluster type processing unit
52 . . . CVD chamber
53 . . . conveying chamber
61 . . . first sputtering chamber
62 . . . second sputtering chamber
63 . . . buffer chamber
70 . . . posture changing chamber
81 . . . target plate
82 . . . backing plate
83 . . . magnet
100 . . . vacuum processing apparatus
Tc, Ts . . . sputtering cathode
Tc1 to Tc5 . . . target portion

1. A sputtering apparatus for forming a thin-film on a surface of a substrate, comprising:
a vacuum chamber capable of keeping a vacuum state;
a plurality of targets, which are linearly arranged in an inside of the vacuum chamber, and each of which includes a surface to be sputtered;
a supporting portion, which has a supporting region for supporting the substrate, and is fixed in the inside of the vacuum chamber; and
a plasma generation means for generating plasma for sputtering the surface to be sputtered of each of the targets, along an arrangement direction of the targets in sequence.

2. The sputtering apparatus according to claim 1, wherein
a target portion of the plurality of targets, which is positioned on a most upstream side in the arrangement direction, is positioned in an outside of the supporting region, and
the target portions cause sputtered particles, which are generated when the target portion is sputtered, to enter the supporting portion in a direction oblique to the supporting portion.

3. The sputtering apparatus according to claim 2, wherein
the plasma generation means includes a magnet for forming a magnetic field in the surface to be sputtered, and
the magnet is arranged for each of the targets to be movable along the arrangement direction.

4. The sputtering apparatus according to claim 1, wherein
the plurality of targets are made of the same material.

5. A thin-film forming method, comprising:
stabilizing a substrate in an inside of a vacuum chamber in which a plurality of targets are linearly arranged; and
sputtering each of the targets along the arrangement direction thereof in sequence, to thereby form a thin-film on a surface of the substrate.

6. The thin-film forming method according to claim 5, further comprising
positioning a target portion of the plurality of targets, which is positioned on a most upstream side in the arrangement direction, in an outside of a peripheral portion of the substrate, to thereby cause sputtered particles, which are generated when the target portion is sputtered, to enter the substrate in a direction oblique to the substrate.

7. The thin-film forming method according to claim 6, further comprising:
arranging, in each of the targets, a magnet for forming a magnetic field on the surface to be sputtered; and
moving, when each of the targets is being sputtered, the magnet, which is arranged in the target being sputtered, along the arrangement direction.

8. A manufacturing method for a field effect transistor, comprising:
forming a gate insulating film on a substrate;
stabilizing the substrate in an inside of a vacuum chamber in which a plurality of targets each having In—Ga—Zn—O-based composition are linearly arranged; and
sputtering each of the targets along the arrangement direction thereof in sequence, to thereby form an active layer on the gate insulating film.
